(19) United States
(12) Patent Application Publication
(10) Pub. No.: US 2024/0353748 A1
(43) Pub. Date: Oct. 24, 2024

(54) METHOD FOR GENERATING OPTICAL PROXIMITY CORRECTION MODEL AND METHOD FOR FABRICATING SEMICONDUCTOR DEVICE USING THE SAME

(71) Applicant: Samsung Electronics Co., Ltd., Suwon-si (KR)

(72) Inventor: Sang Chul YEO, Suwon-si (KR)

(73) Assignee: Samsung Electronics Co., Ltd., Suwon-si (KR)

(21) Appl. No.: 18/407,673

(22) Filed: Jan. 9, 2024

(30) Foreign Application Priority Data
Apr. 24, 2023 (KR) 10-2023-0053291

(51) Int. Cl. G03F 1/36; G03F 1/70; G03F 1/86; G03F 7/00

(52) U.S. Cl. CPC G03F 1/36; G03F 1/70; G03F 1/86; G03F 7/70441

(57) ABSTRACT

A method for correcting an optical proximity correction (OPC) model is provided. The method comprises measuring a first target CD value at a first measurement point of an SEM image for a target pattern and measuring a second target CD value at a second measurement point, simulating the OPC model by using the first target CD value with respect to a first evaluation point corresponding to the first measurement point on a contour of the OPC model for the target pattern, simulating the OPC model by using the second target CD value with respect to a second evaluation point corresponding to the second measurement point on the contour, and fitting the OPC model with respect to each of the first evaluation point and the second evaluation point.

### CROSS-REFERENCE TO RELATED APPLICATION

This application claims priority from Korean Patent Application No. 10-2023-0053291 filed on Apr. 24, 2023, in the Korean Intellectual Property Office and all the benefits accruing therefrom under 35 U.S.C. 119, the entire contents of which in their entirety are herein incorporated by reference.

### BACKGROUND

### Technical Field

The present disclosure relates to a method for generating an optical proximity correction (OPC) model and a method for fabricating a semiconductor device using the same.

### Description of the Related Art

In general, a method of forming patterns of semiconductor chips includes a photolithography process and an etching process. When a circuit pattern on a mask is transferred onto a substrate through a photolithography process to form a circuit pattern (hereinafter, referred to as “transfer circuit pattern”) on the substrate, a difference between the transfer circuit pattern on the substrate and an actual design circuit pattern is generated. This difference is due to an optical proximity effect in the photolithography process. An optical proximity correction (OPC) method is mainly used in the photolithography process to compensate for the optical proximity effect and to accurately transfer the circuit pattern on the mask onto the substrate. A model-based OPC is a method for correcting the circuit pattern of the mask by applying one model to all full-chips on the substrate.

### BRIEF SUMMARY

An object of the present disclosure is to provide a method for generating an optical proximity correction model, in which accuracy is improved.

Another object of the present disclosure is to provide a method for fabricating a semiconductor device using an optical proximity correction model, in which accuracy is improved.

According to some aspects of the present inventive concept, there is provided a method for generating an optical proximity correction (OPC) model, the method comprising measuring a first target CD value at a first measurement point of an SEM image for a target pattern and measuring a second target CD value at a second measurement point, simulating the OPC model using the first target CD value with respect to a first evaluation point, corresponding to the first measurement point, on a contour of the OPC model, simulating the OPC model using the second target CD value with respect to a second evaluation point, corresponding to the second measurement point, on the contour, and fitting the OPC model to each of the first evaluation point and the second evaluation point.

According to some aspects of the present inventive concept, there is provided a method for correcting an optical proximity correction (OPC) model, the method comprising measuring a target CD value of a target pattern for each of a plurality of measurement points of an SEM image for the target pattern, measuring a simulation CD value of a contour of the first OPC model for each of a plurality of evaluation points of a contour of the first OPC model for the target pattern, the plurality of evaluation points corresponding to the plurality of measurement points, and fitting the first OPC model using all of the target CD value of the plurality of measurement points and all of the simulation CD value of the plurality of evaluation points.

According to some aspects of the present inventive concept, there is provided a method for fabricating a semiconductor device, the method comprising fabricating a mask pattern, and forming a pattern on a substrate using the mask, wherein the fabricating the mask includes designing a layout for the pattern, generating an optical proximity correction model for the layout, correcting the layout using the optical proximity correction model, and fabricating the mask with the corrected layout, and the generating the optical proximity correction model includes measuring a first target CD value at a first measurement point of an SEM image of the pattern and measuring a second target CD value at a second measurement point of the SEM image of the pattern, simulating the OPC model using the first target CD value with respect to a first evaluation point, corresponding to the first measurement point, on a contour of the OPC model, simulating the OPC model using the second target CD value with respect to a second evaluation point, corresponding to the second measurement point, on the contour, and fitting the OPC model to each of the first evaluation point and the second evaluation point.

The objects of the present disclosure are not limited to those mentioned above and additional objects of the present disclosure, which are not mentioned herein, will be clearly understood by those skilled in the art from the following description of the present disclosure.

### BRIEF DESCRIPTION OF THE DRAWINGS

FIG. 1 is a flow chart illustrating a method for generating an optical proximity correction model according to some embodiments.

FIGS. 2 to 5 are views illustrating a method for generating an optical proximity correction model according to some embodiments.

FIGS. 6 to 8 are views illustrating a method for generating an optical proximity correction model according to some other embodiments.

FIG. 9 is a flow chart illustrating a method for generating an optical proximity correction model according to some other embodiments.

FIGS. 10 to 12 are views illustrating a method for generating an optical proximity correction model according to some other embodiments.

FIG. 13 is a block diagram illustrating a photolithography system that uses an optical proximity correction model according to some embodiments.

FIG. 14 is a flow chart illustrating a method for fabricating a semiconductor device according to some embodiments.

FIG. 15 is a conceptual view illustrating a photolithography system that uses a photo mask fabricated in accordance with some embodiments.

FIG. 16 is a view illustrating an example of a photo mask included in the photolithography system of FIG. 15.

FIG. 17 is a view illustrating that a circuit pattern is printed on a substrate by using the photo mask of FIG. 16.

### DETAILED DESCRIPTION OF THE DISCLOSURE

Hereinafter, the embodiments according to technical spirits of the present disclosure will be described with reference to the accompanying drawings.

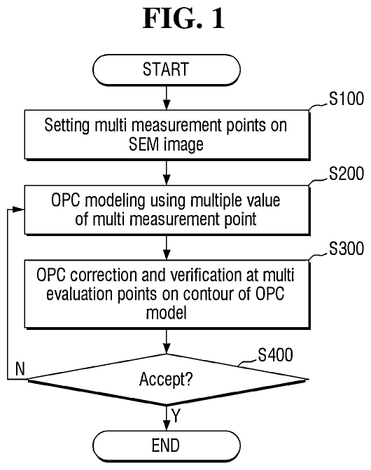

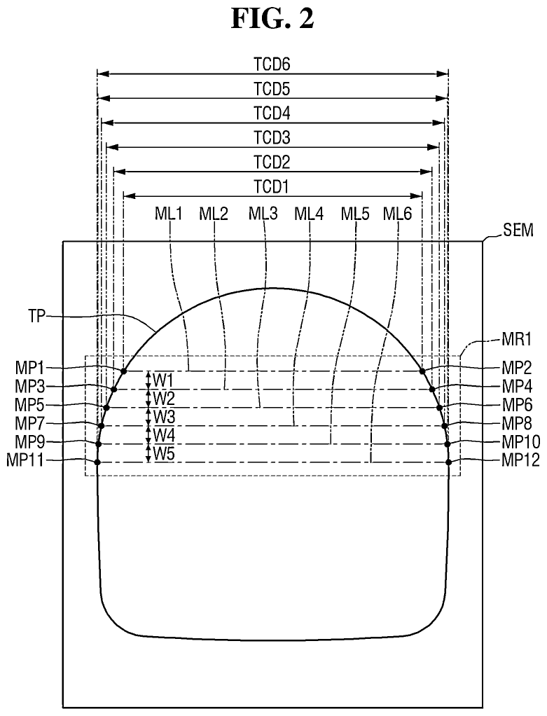

FIG. 1 is a flow chart illustrating a method for generating an optical proximity correction model according to some embodiments. FIGS. 2 to 5 are views illustrating a method for generating an optical proximity correction model according to some embodiments.

Referring to FIGS. 1 to 5, the method for generating an optical proximity correction (OPC) model according to some embodiments may be used to perform an OPC procedure in a process of designing and fabricating a semiconductor device. The optical proximity correction is a technique for correcting a distortion phenomenon (such as a refraction and/or process effect), which, without being limited to a specific theory, occurs due to characteristics of light at the time of exposure using patterns of a design layout.

Referring to FIGS. 1 and 2, a plurality of measurement points are set on an image from an electron microscope (e.g., a scanning electron microscope (SEM) image) (S100).

The SEM image SEM may include a target pattern TP. The target pattern TP may be a pattern to be transferred onto a substrate using the optical proximity correction model.

For example, a first measurement region MR1 may be set in the SEM image SEM. The first measurement region MR1 may include a plurality of measurement points MP1 to MP12. For example, the plurality of measurement points MP1 to MP12 may include first to twelfth measurement points MP1 to MP12. In at least some embodiments, the number of the plurality of measurement points MP1 to MP12 may be randomly set and/or set by a user. The plurality of measurement points MP1 to MP12 may also be referred to as coordinates. Although FIG. 2 shows that the number of the plurality of measurement points MP1 to MP12 is 12, the embodiments are not limited thereto. For example, in at least some embodiments, the plurality of measurement points may be set to 16 in accordance with a user's setup.

A plurality of measurement lines ML1 to ML6 for connecting the plurality of measurement points MP1 to MP12 crosses the target pattern TP. The plurality of measurement lines ML1 to ML6 may also be referred to as a plurality of measurement points. That is, the plurality of measurement points may refer to a portion where a critical dimension (CD) value of a pattern is measured between two coordinates. For example, the first measurement point ML1 may refer to a position for measuring a CD value of the target pattern TP between the first coordinate MP1 and the second coordinate MP2.

The first measurement line ML1 connects the first measurement point MP1 with the second measurement point MP2; the second measurement line ML2 may connect the third measurement point MP3 with the fourth measurement point MP4; the third measurement line ML3 may connect the fifth measurement point MP5 with the sixth measurement point MP6; the fourth measurement line ML4 may connect the seventh measurement point MP7 with the eighth measurement point MP8; the fifth measurement line ML5 may connect the ninth measurement point MP9 with the tenth measurement point MP10; the sixth measurement line ML6 may connect the eleventh measurement point MP11 with the twelfth measurement point MP12; etc.

The plurality of measurement lines ML1 to ML6 may be spaced apart from one another. For example, the first measurement line ML1 and the second measurement line ML2 may be spaced apart from each other by a first interval W1; the second measurement line ML2 and the third measurement line ML3 may be spaced apart from each other by a second interval W2; the third measurement line ML3 and the fourth measurement line ML4 may be spaced apart from each other by a third interval W3; the fourth measurement line ML4 and the fifth measurement line ML5 may be spaced apart from each other by a fourth interval W4; the fifth measurement line ML5 and the sixth measurement line ML6 may be spaced apart from each other by a fifth interval W5; etc.

In at least some embodiments, the plurality of measurement lines ML1 to ML6 may be spaced apart from one another at constant intervals. For example, the first to fifth intervals W1 to W5 may be the same as one another, but the embodiments are not limited thereto, and the intervals among the plurality of measurement lines ML1 to ML6 may be different from one another. For example, the first interval W1 may be greater than the second interval W2 and/or based on the curvature of the first measurement region MR1 between the corresponding plurality of measurement lines ML1 to ML6. The interval at which the plurality of measurement lines ML1 to ML6 are spaced apart from one another may be set by a user.

On the SEM image SEM, the CD value of the target pattern TP may be measured. The CD value of the target pattern TP may be measured using pixel data of the SEM image SEM. For example, the CD value of the target pattern TP may be measured based on a size of the pixel data of the SEM image SEM.

The CD value of the target pattern TP may be measured at the plurality of measurement points MP1 to MP12. For example, the CD value of the target pattern TP may be measured in the plurality of measurement lines ML1 to ML6 passing through the plurality of measurement points MP1 to MP12 on the SEM image SEM.

For example, in the first measurement line ML1 between the first measurement point MP1 and the second measurement point MP2, the target pattern TP may have a first target CD value TCD1; in the second measurement line ML2 between the third measurement point MP3 and the fourth measurement point MP4, the target pattern TP may have a second target CD value TCD2; in the third measurement line ML3 between the fifth measurement point MP5 and the sixth measurement point MP6, the target pattern TP may have a third target CD value TCD3; in the fourth measurement line ML4 between the seventh measurement point MP7 and the eighth measurement point MP8, the target pattern TP may have a fourth target CD value TCD4; in the fifth measurement line ML5 between the ninth measurement point MP9 and the tenth measurement point MP10, the target pattern TP may have a fifth target CD value TCD5; in the sixth measurement line ML6 between the eleventh measurement point MP11 and the twelfth measurement point MP12, the target pattern TP may have a sixth target CD value TCD6; etc.

Subsequently, OPC modeling is performed using the plurality of measurement values of the plurality of measurement points (S200).

The OPC modeling may refer to forming and/or training an OPC model for a mask of the target pattern TP. The OPC model may be formed such that a difference between a CD value of a contour of the OPC model and the plurality of target CD values TCD1 to TCD6 of the target pattern TP, which are measured using the SEM image SEM, is reduced and/or becomes a minimum.

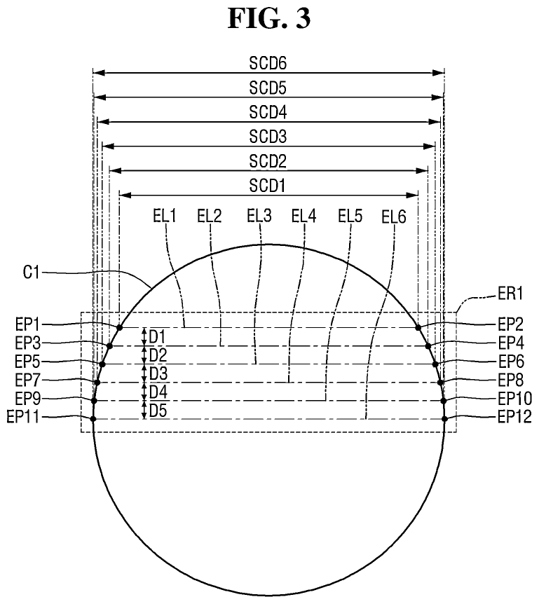

For example, referring to FIG. 2 and FIG. 3, a first contour C1 may be extracted (or generated) from the OPC model. The first contour C1 may have a shape in which a pattern transferred onto a substrate is simulated by a mask fabricated using the formed OPC model.

A first evaluation region ER1 may be set on the first contour C1. The first evaluation region ER1 may correspond to the first measurement region MR1 of the SEM image SEM. The first evaluation region ER1 may include a plurality of evaluation points EP1 to EP12. The plurality of evaluation points EP1 to EP12 may include, for example, first to twelfth evaluation point EP1 to EP12. The plurality of evaluation points EP1 to EP12 may correspond to the plurality of measurement points MP1 to MP12 of the SEM image SEM. The first evaluation point EP1 may correspond to the first measurement point MP1. The second evaluation point EP2 may correspond to the second measurement point MP2. The third evaluation point EP3 may correspond to the third measurement point MP3. The fourth evaluation point EP4 may correspond to the fourth measurement point MP4. Likewise, the fifth to twelfth evaluation points EP5 to EP12 may correspond to the fifth to twelfth measurement points MP5 to MP12, respectively.

The number of the plurality of evaluation points EP1 to EP12 may be the same as the number of the plurality of measurement points MP1 to MP12, but the embodiments are not limited thereto. For example, in at least some embodiments, the number of the plurality of evaluation points EP1 to EP12 and the number of the plurality of measurement points MP1 to MP12 may be different from each other. The plurality of evaluation points EP1 to EP12 may be randomly set and/or set by a user. Although FIG. 3 shows that the number of the plurality of evaluation points EP1 to EP12 is 12, the embodiments are not limited thereto. For example, in at least some embodiments the plurality of evaluation points may be set to 10 or 16 in accordance with a user's setup.

A plurality of evaluation lines EL1 to EL6 for connecting the plurality of evaluation points EP1 to EP12 may be extended on the first contour C1; the plurality of evaluation lines EL1 to EL6 for connecting the plurality of evaluation points EP1 to EP12 may cross the first contour C1; the first evaluation line EL1 may connect the first evaluation point EP1 with the second evaluation point EP2; the first evaluation line EL1 may correspond to the first measurement line ML1. The second evaluation line EL2 may connect the third evaluation point EP3 with the fourth evaluation point EP4; the second evaluation line EL2 may correspond to the second measurement line ML2; the third evaluation line EL3 may connect the fifth evaluation point EP5 with the sixth evaluation point EP6; the third evaluation line EL3 may correspond to the third measurement line ML3; the fourth evaluation line EL4 may connect the seventh evaluation point EP7 with the eighth evaluation point EP8; the fourth evaluation line EL4 may correspond to the fourth measurement line ML4; the fifth evaluation line EL5 may connect the ninth evaluation point EP9 with the tenth evaluation point EP10; the fifth evaluation line EL5 may correspond to the fifth measurement line ML5; the sixth evaluation line EL6 may connect the eleventh evaluation point EP11 with the twelfth evaluation point EP12. The sixth evaluation line EL6 may correspond to the sixth measurement line ML6; etc.

The plurality of evaluation lines EL1 to EL6 may be spaced apart from one another. For example, the first evaluation line EL1 and the second evaluation line EL2 may be spaced apart from each other by a first spaced distance D1; the second evaluation line EL2 and the third evaluation line EL3 may be spaced apart from each other by a second spaced distance D2; the third evaluation line EL3 and the fourth evaluation line EL4 may be spaced apart from each other by a third spaced distance D3; the fourth evaluation line EL4 and the fifth evaluation line EL5 may be spaced apart from each other by a fourth spaced distance D4; the fifth evaluation line EL5 and the sixth evaluation line EL6 may be spaced apart from each other by a fifth spaced distance D5; etc.

The plurality of evaluation lines EL1 to EL6 may be spaced apart from one another at constant intervals. For example, the first to fifth spaced distances D1 to D5 may be the same as one another, but the embodiments are not limited thereto, and, for example, the intervals among the plurality of evaluation lines EL1 to EL6 may be different from one another. For example, the first spaced distance D1 may be greater than the second spaced distance D2 and/or based on the curvature of the first contour C1 between the corresponding plurality of evaluation lines EL1 to EL6. The distance at which the plurality of evaluation lines EL1 to EL6 are spaced apart from one another may be set by a user.

In at least some embodiments, the distance at which the plurality of evaluation lines EL1 to EL6 are spaced apart from one another may be the same as the distance at which the plurality of measurement lines ML1 to ML6 are spaced apart from one another. For example, the first spaced distance D1 may be the same as the first interval W1; the second spaced distance D2 may be the same as the second interval W2; the third spaced distance D3 may be the same as the third interval W3; the fourth spaced distance D4 may be the same as the fourth interval W4; the fifth distance D5 may be same as the fifth interval W5; etc. However, the embodiments are not limited to the above example. For example, the distance at which the plurality of evaluation lines EL1 to EL6 are spaced apart from one another may be different from the distance at which the plurality of measurement lines ML1 to ML6 are spaced apart from one another.

On the first contour C1, a CD value of the first contour C1 may be evaluated. The CD value of the first contour C1 may be evaluated at the plurality of evaluation points EP1 to EP12. The CD value of the first contour C1 may be evaluated in the plurality of evaluation lines EL1 to EL6 passing through the plurality of evaluation points EP1 to EP12. CD values of the plurality of evaluation lines EL1 to EL6 may be respectively evaluated using the plurality of target CD values TCD1 to TCD6 of the plurality of measurement lines ML1 to ML6 corresponding thereto.

For example, the first contour C1 in the first evaluation line EL1 may have a first simulation CD value SCD1. The first simulation CD value SCD1 in the first evaluation line EL1 of the first contour C1 may be evaluated using the first target CD value TD1 in the first measurement line ML1 of the target pattern TP. The first simulation CD value SCD1 may be evaluated as compared with the first target CD value TCD1. For example, a difference between the first simulation CD value SCD1 and the first target CD value TCD1 may be calculated.

The first contour C1 in the second evaluation line EL2 may have a second simulation CD value SCD2. The second simulation CD value SCD2 in the second evaluation line EL2 of the first contour C1 may be evaluated using the second target CD value TCD2 in the second measurement line ML2 of the target pattern TP. The second simulation CD value SCD2 may be evaluated as compared with the second target CD value TCD2. For example, a difference between the second simulation CD value SCD2 and the second target CD value TCD2 may be calculated.

The first contour C1 in the third evaluation line EL3 may have a third simulation CD value SCD3. The third simulation CD value SCD3 in the third evaluation line EL3 of the first contour C1 may be evaluated using the third target CD value TCD3 in the third measurement line ML3 of the target pattern TP. The third simulation CD value SCD3 may be evaluated as compared with the third target CD value TCD3. For example, a difference between the third simulation CD value SCD3 and the third target CD value TCD3 may be calculated.

The first contour C1 in the fourth evaluation line EL4 may have a fourth simulation CD value SCD4. The fourth simulation CD value SCD4 in the fourth evaluation line EL4 of the first contour C1 may be evaluated using the fourth target CD value TCD4 in the fourth measurement line ML4 of the target pattern TP. The fourth simulation CD value SCD4 may be evaluated as compared with the fourth target CD value TCD4. For example, a difference between the fourth simulation CD value SCD4 and the fourth target CD value TCD4 may be calculated.

The first contour C1 in the fifth evaluation line EL5 may have a fifth simulation CD value SCD5. The fifth simulation CD value SCD5 in the fifth evaluation line EL5 of the first contour C1 may be evaluated using the fifth target CD value TCD5 in the fifth measurement line ML5 of the target pattern TP. The fifth simulation CD value SCD5 may be evaluated as compared with the fifth target CD value TCD5. For example, a difference between the fifth simulation CD value SCD5 and the fifth target CD value TCD5 may be calculated.

The first contour C1 in the sixth evaluation line EL6 may have a sixth simulation CD value SCD6. The sixth simulation CD value SCD6 in the sixth evaluation line EL6 of the first contour C1 may be evaluated using the sixth target CD value TCD6 in the sixth measurement line ML6 of the target pattern TP. The sixth simulation CD value SCD6 may be evaluated as compared with the sixth target CD value TCD6. For example, a difference between the sixth simulation CD value SCD6 and the sixth target CD value TCD6 may be calculated.

The OPC modeling may be repeatedly performed using the plurality of simulation CD values SCD1 to SCD6 and the plurality of target CD values TCD1 to TCD6. For example, the OPC modeling may be repeatedly performed until a difference between the simulation CD values SCD1 to SCD6 and the target CD values TCD1 to TCD6 reaches a minimum.

For example, the OPC modeling may be repeatedly performed using [Equation 1]. [Equation 1] represents a cost function using the difference between the simulation CD values SCD1 to SCD6 and the target CD values TCD1 to TCD6, wherein Wx represents a Target CD value, y represents a simulation CD value, and m represents the number of evaluation points.

$$COST = \frac{1}{m} {\sum }_{i = 1}^{m} {( W {x}^{i} - {y}^{i} )}^{2} \qquad [ Equation 1 ]$$

The OPC modeling may be repeatedly performed until a function value of the cost function for the simulation CD values SCD1 to SCD6 and the target CD values TCD1 to TCD6 reaches a minimum. Alternatively, the OPC modeling may be repeatedly performed such that an OPC model corresponding to the case that the function value of the cost function for the simulation CD values SCD1 to SCD6 and the target CD values TCD1 to TCD6 is smaller than a threshold value (e.g., set by a user) is output.

In these cases, repeatedly performing the OPC modeling may include correcting a previously modeled OPC model. For example, a first OPC model that is primarily generated may be corrected to secondarily generate a second OPC model. In this case, when a cost function value of the first OPC model is greater than that of the second OPC model, the second OPC model may be adopted. Likewise, the second OPC model may be corrected to generate a third OPC model, and in this case, when a cost function value of the third OPC model is smaller than that of the second OPC model, the third OPC model may be adopted. On the other hand, when the cost function value of the second OPC model is smaller than that of the third OPC model, the second OPC model not the third OPC model may be adopted.

For example, referring to FIGS. 2 to 4, when a cost function value of the first OPC model for extracting the first contour C1 is greater than a threshold value, the first OPC model may be corrected so that the second OPC model for extracting a second contour C2 may be generated.

When a cost function value for the first to sixth simulation CD values SCD1′ to SCD6′ of the first contour C1 extracted from the first OPC model and the first to sixth target CD values TCD1 to TCD6 of the SEM image SEM is greater than a preset threshold value, the second OPC model from which the first OPC model is corrected may be generated.

Similarly, when a cost function value for the first to sixth simulation CD values SCD1′ to SCD6′ of the second contour C2 extracted from the second OPC model and the first to sixth target CD values TCD1 to TCD6 of the SEM image SEM is greater than the preset threshold value, the second OPC model may be corrected.

The OPC modeling may include fitting for the plurality of evaluation points. The OPC model may be fitted in each of the first to sixth evaluation lines EL1 to EL6. For example, the first simulation CD value SCD1 of the first evaluation line EL1 may be compared with the first target CD value TCD1 of the first measurement line ML1 so that the OPC model may be corrected to change the CD value of the first evaluation line EL1. The second simulation CD value SCD2 of the second evaluation line EL2 may be compared with the second target CD value TCD2 of the second measurement line ML2 so that the OPC model may be corrected to change the CD value of the second evaluation line EL2. That is, the OPC model may be fitted using each of the first to sixth target CD values TCD1 to TCD6 measured in the SEM image SEM and the first to sixth simulation CD values SCD1′ to SCD6′ of the first contour C1 corresponding thereto.

Referring to FIGS. 2 and 3, a function value of a cost function for an average value of the first to sixth simulation CD values SCD1 to SCD6 of the first contour C1 extracted from the first OPC model and an average value of the first to sixth target CD values TCD1 to TCD6 of the target pattern TP may be smaller than the preset threshold value. However, the function value of the cost function for each of the first to sixth simulation CD values SCD1 to SCD6 and the first to sixth target CD values TCD1 to TCD6 may be greater than the preset threshold value. For example, even though the function value of the cost function for the first to fifth simulation CD values SCD1 to SCD5 and the first to fifth target CD values TCD1 to TCD5 is smaller than the threshold value, a function value of a cost function for the sixth simulation CD value SCD6 and the sixth target CD value TCD6 may be greater than the threshold value. In this case, correction of the first OPC model for extracting the first contour C1 is required. Therefore, accuracy of the OPC model generated when OPC modeling is performed using the plurality of evaluation points EP1 to EP12 may be improved.

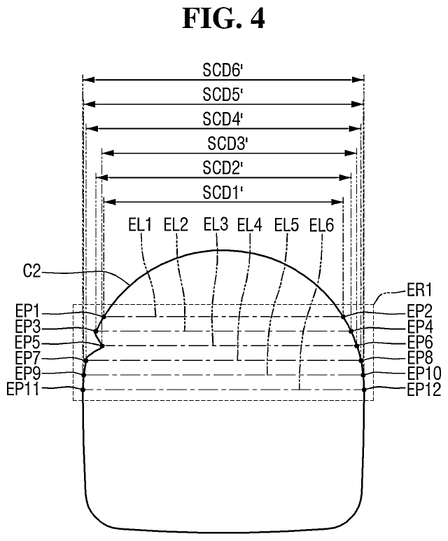

Likewise, referring to FIGS. 2 and 4, the function value of the cost function for the average value of the first to sixth simulation CD values SCD1′ to SCD6′ of the second contour C2 extracted from the second OPC model and the average value of the first to sixth target CD values TCD1 to TCD6 of the target pattern TP may be smaller than the preset threshold value. However, the function value of the cost function for each of the first simulation CD value SCD1′, the second simulation CD value SCD2′, the fourth to sixth simulation CD values SCD4′ to SCD6′, the first target CD value TCD1, the second target CD value TCD2, and the fourth to sixth target CD values TCD4 to TCD6 may be greater than the preset threshold value. Therefore, the second OPC model for extracting the second contour C2 may be corrected so that a new OPC model may be generated.

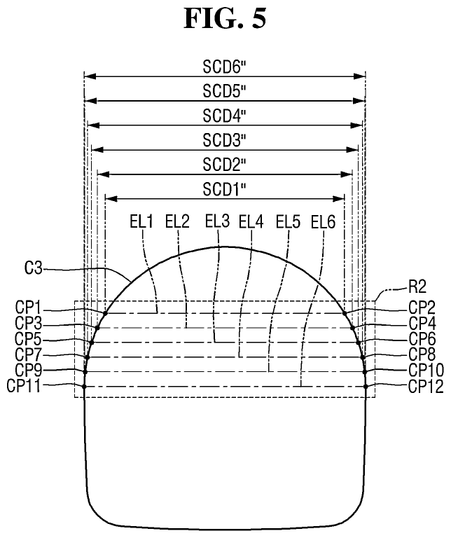

Referring to FIG. 5, a third contour C3 may be extracted from the third OPC model generated by correcting the second OPC model. A function value of a cost function for each of the first to sixth simulation CD values SCD1″ to SCD6″ on the third contour C3 and the first to sixth target CD values TCD1 to TCD6 of the target pattern TP may be smaller than a function value of a cost function using each of the first to sixth simulation CD values SCD1″ to SCD6 on the second contour C2.

Next, referring to FIGS. 1, 2 and 5, the OPC model is verified at a plurality of evaluation points of a contour (S300).

An edge placement error (EPE) may be calculated at the plurality of evaluation points of the contour extracted from the generated OPC model. For example, an EPE between a plurality of evaluation points EP1 to EP12 of the third contour C3 and a plurality of measurement points MP1 to MP12 of the target pattern TP may be calculated.

An EPE between the first evaluation point EP1 and the first measurement point MP1 of the target pattern TP of the SEM image SEM may be calculated. An EPE between the second evaluation point EP2 of the third contour C3 and the second measurement point MP2 of the target pattern TP of the SEM image SEM may be calculated. An EPE between the third evaluation point EP3 of the third contour C3 and the third measurement point MP3 of the target pattern TP of the SEM image SEM may be calculated. An EPE between the fourth evaluation point EP4 of the third contour C3 and the fourth measurement point MP4 of the target pattern TP of the SEM image SEM may be calculated. Likewise, an EPE between each of the fifth to twelfth evaluation points EP5 to EP12 and each of the fifth to twelfth measurement points MP5 to MP12 may be calculated.

Subsequently, when verification of the OPC model passes the criterion, the OPC modeling is ended, and when verification of the OPC model does not pass the criterion, the OPC modeling is performed again (S400).

For example, when the EPE between the plurality of evaluation points EP1 to EP12 of the third contour C3 and the plurality of measurement points MP1 to MP12 of the target pattern TP is smaller than the preset threshold value, the OPC model for extracting the third contour C3 may be generated as a final OPC model. On the other hand, when the EPE between the plurality of evaluation points EP1 to EP12 of the third contour C3 and the plurality of measurement points MP1 to MP12 of the target pattern TP is greater than the preset threshold value, modeling may be performed to generate a new OPC model by correcting the OPC model for extracting the third contour C3.

When OPC modeling is performed using the plurality of evaluation points, accuracy of the OPC model may be improved. For example, referring to FIGS. 2 and 4, a difference between the third target CD value TCD3 and the third simulation CD value SCD3′ may be greater than a difference between the third target CD value TCD3 and each of the first simulation CD value SCD1′, the second simulation CD value SCD2′ and the fourth to sixth simulation CD values SCD4′ to SCD6′. The third simulation CD value SCD3′ in the third evaluation line EL3 may be smaller than the third target CD value TCD3 in the third measurement line ML3.

Meanwhile, when the average value of the plurality of simulation CD values SCD1 to SCD6 is compared with the average value of the plurality of target CD values TCD1 to TCD6 without respectively comparing the plurality of simulation CD values SCD1 to SCD6 with the plurality of target CD values TCD1 to TCD6, a function value of a cost function for the average value of the plurality of simulation CD values SCD1 to SCD6 of the second contour C2 and the average value of the plurality of measurement CD values may be smaller than the threshold value. On the other hand, the function value of the cost function for each of the first to sixth simulation CD values SCD1 to SCD6 and each of the first to sixth target CD values TCD1 to TCD6 may be greater than the threshold value.

For example, when verification is performed using an average value without being performed on the plurality of evaluation points, a corresponding OPC model may be generated by satisfying a verification criterion even though an optical proximity correction effect of the corresponding OPC model is not sufficient. Additionally, when verification is performed using an average value without being performed on the plurality of evaluation points, the excessive kernel usage and/or over-fitting of the corresponding OPC model may be prevented and/or mitigated.

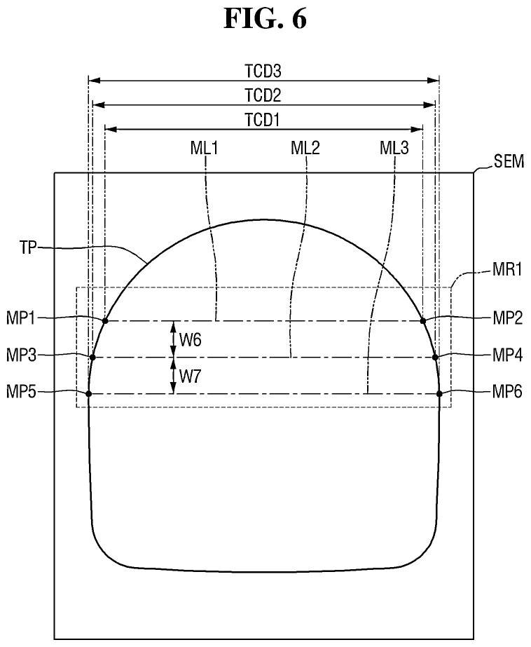

FIGS. 6 to 8 are views illustrating a method for generating an optical proximity correction model according to some other embodiments. For convenience of description, the following description will be based on differences from that made with reference to FIGS. 1 to 5.

Referring to FIG. 6, the first measurement region MR1 may be set on the SEM image SEM. The first measurement region MR1 may include a plurality of measurement points MP1 to MP6. The plurality of measurement points MP1 to MP6 may include first to sixth measurement points MP1 to MP6.

The first measurement line ML1 and the second measurement line ML2 may be spaced apart from each other by a sixth interval W6. The second measurement line ML2 and the third measurement line ML3 may be spaced apart from each other by a seventh interval W7. The sixth interval W6 and the seventh interval W7 may be constant, but the embodiments are not limited thereto. For example, the sixth interval W6 and the seventh interval W7 may be different from each other.

Referring to FIG. 6 in comparison with FIG. 2, the sixth interval W6 and the seventh interval W7 may be greater than the first to fifth intervals W1 to W5. In addition, the first measurement regions MR1 of FIG. 6 may include a smaller number of measurement points than those of the first measurement region MR1 of FIG. 2.

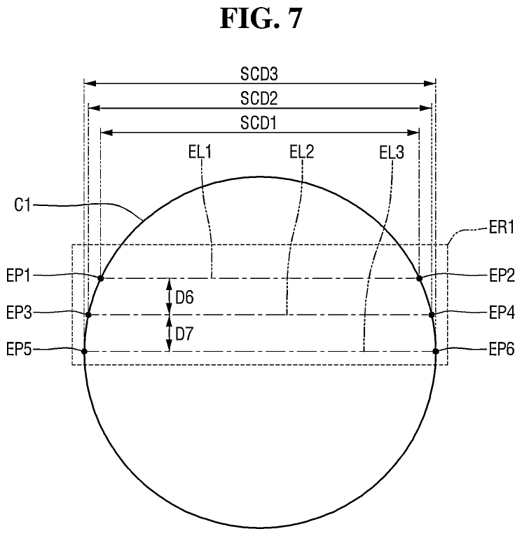

Referring to FIG. 7, the first evaluation region ER1 may be set on the first contour C1. The first evaluation region ER1 may correspond to the first measurement region MR1 of the SEM image SEM. The first evaluation region ER1 may include a plurality of evaluation points EP1 to EP6. The plurality of evaluation points EP1 to EP6 may include first to sixth evaluation points EP1 to EP6.

The first evaluation line EL1 and the second evaluation line EL2 may be spaced apart from each other by a sixth spaced distance D6. The second evaluation line EL2 and the third evaluation line EL3 may be spaced apart from each other by a seventh spaced distance D7. The sixth interval W6 and the seventh interval W7 may be constant, but the embodiments are not limited thereto. For example, the sixth spaced distance D6 and the seventh spaced distance D7 may be different from each other.

Referring to FIG. 7 in comparison with FIG. 3, the sixth spaced distance D6 and the seventh spaced distance D7 may be greater than the first to fifth spaced distances D1 to D5. In addition, the first evaluation region ER1 of FIG. 7 may include a smaller evaluation point than those of the first evaluation region ER1 of FIG. 2.

When a function value of a cost function for the first to third simulation CD values SCD1 to SCD3 on the first to third evaluation lines EL1 to EL3 of the first contour C1 and the first to third target CD values TCD1 to TCD3 on the first to third measurement lines ML1 to ML3 of the target pattern TP of the SEM image SEM is greater than the preset threshold value, the OPC model for extracting the first contour C1 may be corrected. For example, the OPC model for extracting the first contour C1 may be fitted. The fitting of the OPC model may be performed for each of the first to third evaluation lines EL1 to EL3.

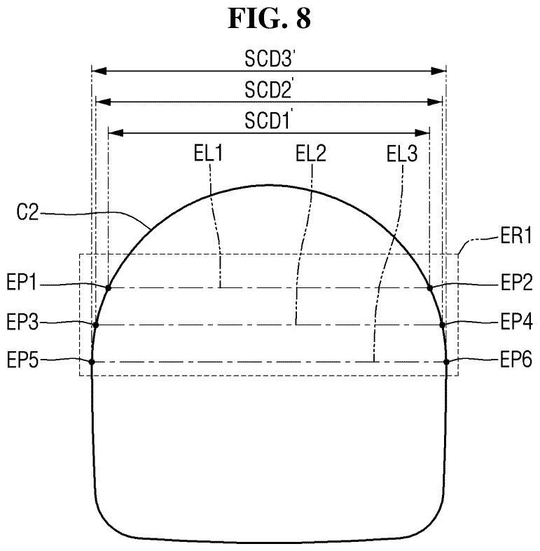

Referring to FIG. 8, the second contour C2 may be extracted from a new OPC model obtained by correcting the OPC model for extracting the first contour C1. A function value of a cost function for each of the first to third simulation CD values SCD1 to SCD3 of the second contour C2 and each of the first to third target CD values TCD1 to TCD3 of the target pattern TP may be smaller than the preset threshold value. In this case, correction of the OPC model may not be additionally performed.

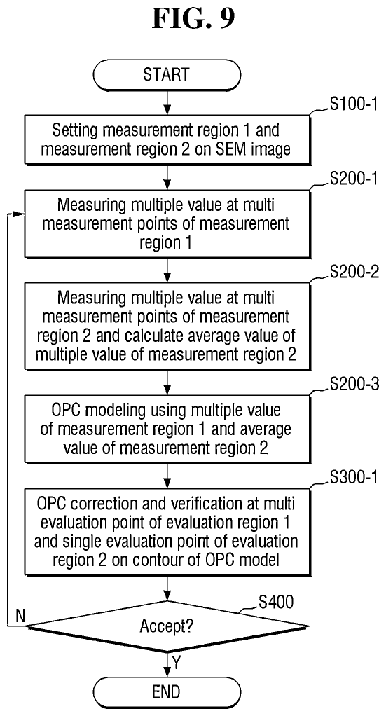

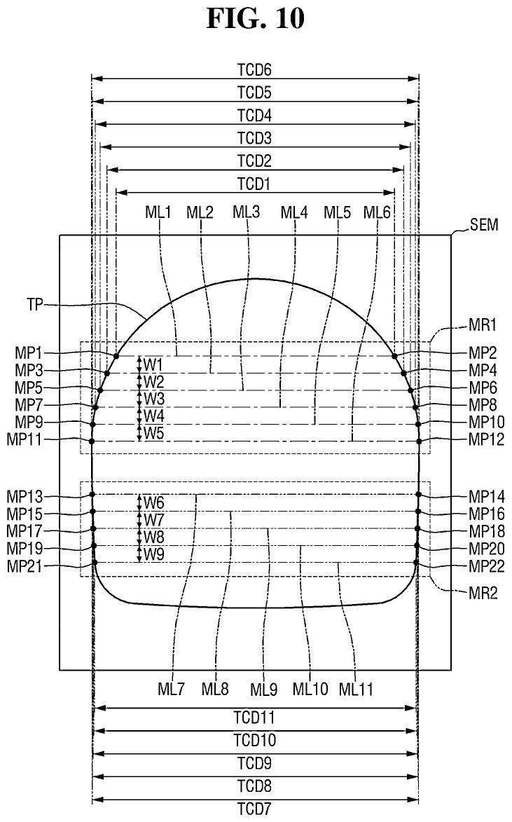

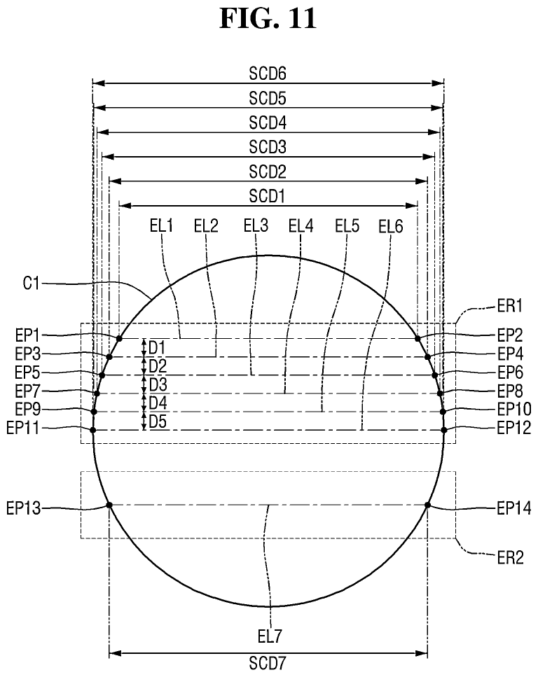

FIG. 9 is a flow chart illustrating a method for generating an optical proximity correction model according to some other embodiments. FIGS. 10 to 12 are views illustrating a method for generating an optical proximity correction model according to some other embodiments. For convenience of description, the following description will be based on differences from that made with reference to FIGS. 1 to 5.

Referring to FIGS. 9 and 10, a plurality of measurement regions are set on the SEM image (S100-1).

The SEM image SEM may include the target pattern TP. The first measurement region MR1 and the second measurement region MR2 may be set on the SEM image SEM. The first measurement region MR1 and the second measurement region MR2 may include a portion of the target pattern TP. In at least some embodiments, the sizes of the first measurement region MR1 and the second measurement region MR2 may be different from each other, but the embodiments are not limited thereto. For example, the sizes of the first measurement region MR1 and the second measurement region MR2 may be the same as each other.

The first measurement region MR1 may include the first to twelfth measurement points MP1 to MP12. Additionally, the second measurement region MR2 may include thirteenth to twenty-second measurement points MP13 to MP22. The number of the plurality of measurement points MP1 to MP22 may be randomly set and/or set by a user. For example, the number of measurement points included in the first measurement region MR1 and the number of measurement points included in the second measurement region MR2 may be randomly set by a user.

The first measurement region MR1 may include first to sixth measurement lines ML1 to ML6. The first measurement line ML1 may connect the first measurement point MP1 with the second measurement point MP2; the second measurement line ML2 may connect the third measurement point MP3 with the fourth measurement point MP4; the third measurement line ML3 may connect the fifth measurement point MP5 with the sixth measurement point MP6; the fourth measurement line ML4 may connect the seventh measurement point MP7 with the eighth measurement point MP8; the fifth measurement line ML5 may connect the ninth measurement point MP9 with the tenth measurement point MP10; the sixth measurement line ML6 may connect the eleventh measurement point MP11 with the twelfth measurement point MP12; etc.

The first to sixth measurement lines ML1 to ML6 may be spaced apart from one another; the first measurement line ML1 and the second measurement line ML2 may be spaced apart from each other by a first interval W1; the second measurement line ML2 and the third measurement line ML3 may be spaced apart from each other by a second interval W2; the third measurement line ML3 and the fourth measurement line ML4 may be spaced apart from each other by a third interval W3; the fourth measurement line ML4 and the fifth measurement line ML5 may be spaced apart from each other by a fourth interval W4; the fifth measurement line ML5 and the sixth measurement line ML6 may be spaced apart from each other by a fifth interval W5; etc.

The first to sixth measurement lines ML1 to ML6 may be spaced apart from one another at constant intervals. For example, the first to fifth intervals W1 to W5 may be the same as one another, but the embodiments are not limited thereto, and the intervals among the first to sixth measurement lines ML1 to ML6 may be different from one another. For example, the first interval W1 may be greater than the second interval W2. The interval at which the first to sixth measurement lines ML1 to ML6 are spaced apart from one another may be set by a user.

The second measurement region MR2 may include seventh to eleventh measurement lines ML7 to ML11; the seventh measurement line ML7 may connect the thirteenth measurement point MP13 with the fourteenth measurement point MP14; the eighth measurement line ML8 may connect the fifteenth measurement point MP15 with the sixteenth measurement point MP16; the ninth measurement line ML9 may connect the seventeenth measurement point MP17 with the eighteenth measurement point MP18; the tenth measurement line ML10 may connect the nineteenth measurement point MP19 with the twentieth measurement point MP20; the eleventh measurement line ML11 may connect the twenty-first measurement point MP21 with the twenty-second measurement point MP22; etc.

The seventh to eleventh measurement lines ML7 to ML11 may be spaced apart from one another. The seventh measurement line ML7 and the eighth measurement line ML8 may be spaced apart from each other by a sixth interval W6. The eighth measurement line ML8 and the ninth measurement line ML9 may be spaced apart from each other by a seventh interval W7. The ninth measurement line ML9 and the tenth measurement line ML10 may be spaced apart from each other by an eighth interval W8. The tenth measurement line ML10 and the eleventh measurement line ML11 may be spaced apart from each other by a ninth interval W9.

The seventh to eleventh measurement lines ML7 to ML11 may be spaced apart from one another at constant intervals. For example, the sixth to ninth intervals W6 to W9 may be the same as one another, but the embodiments are not limited thereto, and the intervals among the seventh to eleventh measurement lines ML7 to ML11 may be different from one another. For example, the sixth interval W6 may be greater than the seventh interval W7. The interval at which the seventh to eleventh measurement lines ML7 to ML11 are spaced apart from one another may be set by a user.

The interval at which the first to sixth measurement line ML1 to ML6 are spaced apart from one another and the interval at which the seventh to eleventh measurement lines ML7 to ML11 are spaced apart from one another may be the same. For example, the first to fifth intervals W1 to W5 may be the same as the sixth to ninth intervals W6 to W9. Alternatively, the interval at which the first to sixth measurement line ML1 to ML6 are spaced apart from one another and the interval at which the seventh to eleventh measurement lines ML7 to ML11 are spaced apart from one another may be different from each other. For example, the first to fifth intervals W1 to W5 may be different from the sixth to ninth intervals W6 to W9.

Subsequently, a plurality of CD values are measured at a plurality of measurement points of the first measurement region (S200-1).

The CD value of the target pattern TP may be measured at the first to twelfth measurement points MP1 to MP12 of the first measurement region MR1. For example, the CD value of the target pattern TP may be measured in the first to sixth measurement lines ML1 to ML6 of the first measurement region MR1 on the SEM image SEM.

The target pattern TP in the first measurement line ML1 between the first measurement point MP1 and the second measurement point MP2 may have a first target CD value TCD1; the target pattern TP in the second measurement line ML2 between the third measurement point MP3 and the fourth measurement point MP4 may have a second target CD value TCD2; the target pattern TP in the third measurement line ML3 between the fifth measurement point MP5 and the sixth measurement point MP6 may have a third target CD value TCD3; the target pattern TP in the fourth measurement line ML4 between the seventh measurement point MP7 and the eighth measurement point MP8 may have a fourth target CD value TCD4; the target pattern TP in the fifth measurement line ML5 between the ninth measurement point MP9 and the tenth measurement point MP10 may have a fifth target CD value TCD5; the target pattern TP in the sixth measurement line ML6 between the eleventh measurement point MP11 and the twelfth measurement point MP12 may have a sixth target CD value TCD6; etc.

Subsequently, a plurality of CD values are measured at a plurality of measurement points of the second measurement region, and an average value of the plurality of CD values of the second measurement region is calculated (S200-2).

The CD value of the target pattern TP may be measured at the thirteenth to twenty-second measurement points MP13 to MP22 of the second measurement region MR2. For example, the CD value of the target pattern TP may be measured in the seventh to eleventh measurement lines ML7 to ML11 of the second measurement region MR2 on the SEM image SEM.

For example, in the seventh measurement line ML7 between the thirteenth measurement point MP13 and the fourteenth measurement point MP14, the target pattern TP may have a seventh target CD value TCD7; in the eighth measurement line ML8 between the fifteenth measurement point MP15 and the sixteenth measurement point MP16, the target pattern TP may have an eighth target CD value TCD8; in the ninth measurement line ML9 between the seventeenth measurement point MP17 and the eighteenth measurement point MP18, the target pattern TP may have a ninth target CD value TCD9; in the tenth measurement line ML10 between the nineteenth measurement point MP19 and the twentieth measurement point MP20, the target pattern TP may have a tenth target CD value TCD10; in the eleventh measurement line ML11 between the twenty-first measurement point MP21 and the twenty-second measurement point MP22, the target pattern TP may have an eleventh target CD value TCD11; etc.

An average value of the seventh to eleventh target CD values TCD7 to TCD11 may be calculated using the seventh to eleventh target CD values TCD7 to TCD11 of the second measurement region MR2. Hereinafter, the average value of the seventh to eleventh target CD values TCD7 to TCD11 of the second measurement region MR2 will be referred to as an average target CD value.

Subsequently, OPC modeling is performed using the plurality of target CD values of the first measurement region and the average target CD value of the second measurement region (200-3).

Referring to FIGS. 9, 10, and 11, the first contour C1 may be extracted from the OPC model.

The first evaluation region ER1 and the second evaluation region ER2 may be set on the first contour C1. The first evaluation region ER1 may correspond to the first measurement region MR1 of the SEM image SEM. The second evaluation region ER2 may correspond to the second measurement region MR2 of the SEM image SEM.

The first evaluation region ER1 may include first to twelfth evaluation points EP1 to EP12. The first to twelfth evaluation points EP1 to EP12 may correspond to the first to twelfth measurement points MP1 to MP12, respectively. The number of the first to twelfth evaluation points EP1 to EP12 may be the same as the number of the first to twelfth measurement points MP1 to MP12, but the embodiments are not limited thereto. For example, the number of first to twelfth evaluation points EP1 to EP12 and the number of first to twelfth measurement points MP1 to MP12 may be different from each other.

The first evaluation region ER1 may include first to sixth evaluation lines EL1 to EL6. The first to sixth evaluation lines EL1 to EL6 may be spaced apart from one another at constant intervals. That is, the first to fifth spaced distance D1 to D5 may be the same as one another, but the embodiments are not limited thereto, and the intervals among the first to sixth evaluation lines EL1 to EL6 may be different from one another. For example, the first spaced distance D1 may be greater than the second spaced distance D2. The interval at which the first to sixth evaluation lines EL1 to EL6 are spaced apart from one another may be set by a user.

The second evaluation region ER2 may include the thirteenth evaluation point EP13 and the fourteenth evaluation point EP14. The thirteenth evaluation point EP13 and the fourteenth evaluation point EP14 may be randomly set. The second evaluation region ER2 may include the seventh evaluation line EL7.

On the first contour C1, the CD value of the first contour C1 may be evaluated. The CD value of the first contour C1 may be evaluated at the plurality of evaluation points EP1 to EP14. The CD value of the first contour C1 may be evaluated in the plurality of evaluation lines EL1 to EL7 passing through the plurality of evaluation points EP1 to EP14.

The CD values of the first to sixth evaluation lines EL1 to EL6 of the first evaluation region ER1 may be evaluated using the first to sixth target CD values TCD1 to TCD6 of the first to sixth measurement lines ML1 to ML6 of the first measurement region MR1 corresponding to the first evaluation region ER1. The CD value of the seventh evaluation line EL7 of the second evaluation region ER2 may be evaluated using the average target CD value of the seventh to eleventh target CD values TCD7 to TCD11 of the seventh to eleventh measurement lines ML7 to ML11 of the second measurement region MR2.

In the first to sixth evaluation lines EL1 to EL6 of the first evaluation region ER1, the first contour C1 may have first to sixth simulation CD values SCD1 to SCD6. The first to sixth simulation CD values SCD1 to SCD6 in the first to sixth evaluation lines EL1 to EL6 of the first contour C1 may be evaluated using the first to sixth target CD values TCD1 to TCD6 in the first to sixth measurement lines ML1 to ML6 of the target pattern TP. Each of the first to sixth simulation CD values SCD1 to SCD6 may be evaluated in comparison with each of the first to sixth target CD values TCD1 to TCD6. For example, a difference between each of the first to sixth simulation CD values SCD1 to SCD6 and each of the first to sixth target CD values TCD1 to TCD6 may be calculated.

In the seventh evaluation line EL7 of the second evaluation region ER2, the first contour C1 may have a seventh simulation CD value SCD7. The seventh simulation CD value SCD7 in the seventh evaluation line EL7 of the first contour C1 may be evaluated using an average target CD value of the seventh to eleventh target CD values TCD7 to TCD11 in the seventh to eleventh measurement lines ML7 to ML11 of the target pattern TP. The seventh simulation CD value SCD7 may be evaluated in comparison with the average target CD value of the seventh to eleventh target CD values TCD7 to TCD11. For example, a difference between the seventh simulation CD value SCD7 and the average target CD value of the seventh to eleventh target CD values TCD7 to TCD11 may be calculated.

The OPC modeling may be repeatedly performed using the plurality of simulation CD values SCD1 to SCD7, the first to sixth target CD values TCD1 to TCD6 and the average target CD value. For example, the OPC modeling may be repeatedly performed until the difference between the first to sixth simulation CD values SCD1 to SCD6 and the first to sixth target CD values TCD1 to TCD6 becomes minimum and the difference between the seventh simulation CD value SCD7 and the average target CD value becomes minimum.

That is, the OPC model may be fitted to each of the first to sixth evaluation lines EL1 to EL6 in the first evaluation region ER1, and the OPC model may be fitted to only the seventh evaluation lines EL7 in the second evaluation region ER2. The OPC model may be fitted using each of the first to sixth simulation CD values SCD1 to SCD6 of the first evaluation region ER1 and the first to sixth target CD values TCD1 to TCD6 of the first measurement region MR1. In addition, the OPC model may be fitted using the seventh simulation CD value SCD7 of the second evaluation region ER2 and the average target CD value of the second measurement region MR2.

The OPC modeling may be repeatedly performed until the function value of the cost function for the first to seventh simulation CD values SCD1 to SCD7, the first to sixth target CD values TCD1 to TCD6 and the average target CD value becomes minimum. Alternatively, the OPC modeling may be repeatedly performed such that an OPC model corresponding to the case that the function value of the cost function for the first to seventh simulation CD values SCD1 to SCD7, the first to sixth target CD values TCD1 to TCD6 and the average target CD value is smaller than a threshold value set by a user may be output.

Referring to FIGS. 9, 11, and 12, when the function value of the cost function for the first to seventh simulation CD values SCD1′ to SCD7′ of the first contour C1 extracted from the first OPC model, the first to sixth target CD values TCD1 to TCD6 and the average target CD value is greater than a preset threshold value, the first OPC model may be corrected.

In detail, the function value of the cost function for each of the first to sixth simulation CD values SCD1′ to SCD6′ of the first evaluation region ER1 and the first to sixth target CD values TCD1 to TCD6 of the first measurement region MR1 may be smaller than the preset threshold value. However, the function value of the cost function for the seventh simulation CD value SCD7′ of the second evaluation region ER2 and the average target CD value of the second measurement region MR2 may be greater than the preset threshold value. In this case, the first OPC model may be corrected.

Alternatively, the function value of the cost function for the seventh simulation CD value SCD7′ of the second evaluation region ER2 and the average target CD value of the second measurement region MR2 may be smaller than the preset threshold value. However, the function value of the cost function for each of the first to sixth simulation CD values SCD1 to SCD6′ of the first evaluation region ER1 and each of the first to sixth target CD values TCD1 to TCD6 of the first measurement region MR1 may be greater than the preset threshold value. For example, even though the function value of the cost function for the first to fifth simulation CD values SCD1′ to SCD5′ and the first to fifth target CD values TCD1 to TCD5 is smaller than the threshold value, the function value of the cost function for the sixth simulation CD value SCD6′ and the sixth target CD value TCD6 may be greater than the threshold value. Even in this case, the first OPC model may be corrected.

The second contour C2 may be extracted from the second OPC model obtained by correcting the first OPC model. The first OPC model may be corrected when the function value of the cost function for the first to seventh simulation CD values SCD1 to SCD7 (and/or SCD1′ to SCD7′), the first to sixth target CD values TCD1 to TCD6 and the average target CD value is greater than the preset threshold value.

The function value of the cost function for each of the first to sixth simulation CD values SCD1 to SCD6 and SCD1′ to SCD6′ of the first evaluation region ER1 on the second contour C2 and each of the first to sixth target CD values TCD1 to TCD6 of the first measurement region MR1 of the target pattern TP and the function value of the cost function for the seventh simulation CD value SCD7 and SCD7′ of the second evaluation region ER2 and the average target CD value of the second measurement region MR2 may be smaller than the function value of the cost function for each of the first to sixth simulation CD values SCD1 to SCD6 of the first evaluation region ER1 on the contour C1 and each of the first to sixth target CD values TCD1 to TCD6 of the first measurement region MR1 of the target pattern TP and the function value of the cost function for the seventh simulation CD value SCD7 of the second evaluation region ER2 and the average target CD value of the second measurement region MR2.

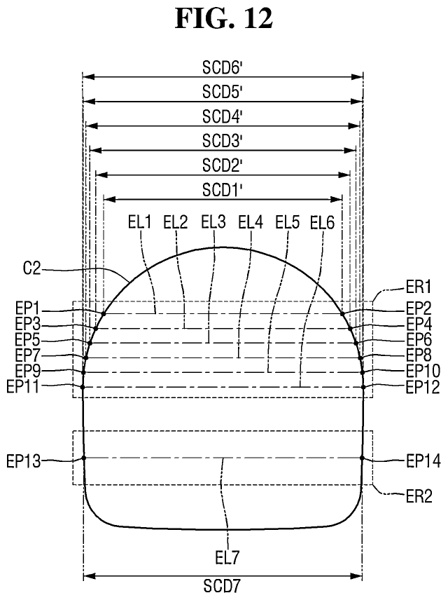

Referring to FIGS. 9 and 12, the OPC model is verified at the plurality of evaluation points of the first evaluation region of the contour and one evaluation point of the second evaluation region (S300-1).

An EPE may be calculated at the plurality of evaluation points of the contour extracted from the generated OPC model. For example, an EPE between the first to twelfth evaluation points EP1 to EP12 of the first evaluation region ER1 of the second contour C2 and the first to twelfth measurement points MP1 to MP12 of the first measurement region MR1 of the target pattern TP may be calculated. In addition, an EPE of the seventh evaluation line EL7 of the second evaluation region ER2 of the second contour C2 may be calculated using the average target CD value of the second measurement region MR2 of the target pattern TP.

Subsequently, when verification of the OPC model passes the criterion, the OPC model is ended, and when verification of the OPC model does not pass the criterion, the OPC modeling is performed again (S400).

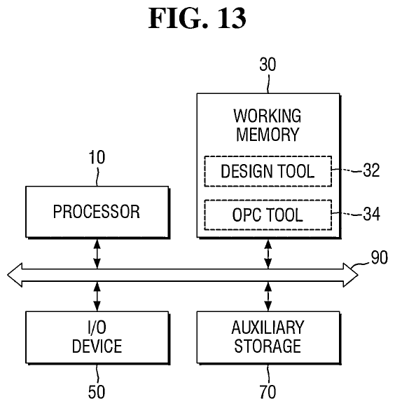

FIG. 13 is a block diagram illustrating a photolithography system that uses an optical proximity correction model according to some embodiments.

Referring to FIG. 13, the photolithography system includes a processor 10, a working memory 30, an input/output device 50, an auxiliary storage device 70, and a system interconnector 90.

For example, the photolithography system may be a dedicated device for generating an optical proximity correction model according to some embodiments, or may be provided as a dedicated device for performing a semiconductor design including the same. For example, the photolithography system may include various design and verification simulation programs.

The processor 10 is configured to execute software (application program, operating system, and device drivers) to be performed in the photolithography system. Although not shown, the processor 10 may execute an operating system (OS) loaded in the working memory 30. The processor 10 may execute various application programs to be driven based on the operating system. For example, the processor 10 may be and/or may include processing circuitry such as hardware including logic circuits; a hardware/software combination such as a processor executing software; and/or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The operating system and/or the application programs may be loaded from the working memory 30. For example, although not shown, when the photolithography system is booted, an OS image stored in the auxiliary storage device 70 may be loaded into the working memory 30 based on a booting sequence. Overall input/output operations of the photolithography system may be supported by the operating system. Similarly, the application programs may be loaded into the working memory 30 to provide a user-selected or basic service. In particular, a design tool 32 for the semiconductor design described above and/or an OPC tool 34 for the method for generating an optical proximity correction model of the present disclosure may be loaded from the auxiliary storage device 70 into the working memory 30. In at least one embodiment, the OPC tool 34 and/or the design tool 32 may include a structure that is trainable, such as an artificial neural network, a decision tree, a support vector machine, a Bayesian network, a genetic algorithm, a convolution neural network (CNN), a generative adversarial network (GAN), a recurrent neural network (RNN), a stacking-based deep neural network (S-DNN), a restricted Boltzmann machine (RBM), a fully convolutional network, a long short-term memory (LSTM) network, a classification network, and/or the like. However, the embodiments are not limited thereto.

The design tool 32 may have a bias function that may change a shape and position of specific layout patterns differently from those defined by the design rule. In addition, the design tool 32 may perform a design rule check (DRC) under the changed bias data condition. The OPC tool 34 may perform optical proximity correction (OPC) for layout data output from the design tool 32.

For example, the working memory 30 may be a volatile memory such as a dynamic random access memory (DRAM) and a static random access memory (SRAM), or may be a non-volatile memory such as a flash memory, a phase change random access memory (PRAM), a resistance random access memory (RRAM), a nano floating gate memory (NFGM), a polymer random access memory (PoRAM), a magnetic random access memory (MRAM) a ferroelectric random access memory (FRAM), and/or the like.

The input/output device 50 is configured to control user input from and output to user interface devices. For example, the input/output device 50 may include an input and/or interface configured for an input device (such as a keyboard, a keypad, a mouse, a touch screen, and/or the like) to receive information from a designer, and/or an output device (such as a printer, a display, and/or the like) to display a process and a result of the design tool 32 and/or the OPC tool 34. A user may receive information on a semiconductor area or data paths, which require adjusting operating characteristics, and/or confirming adjusted operating characteristics, using the input/output device 50.

The auxiliary storage device 70 may be provided as a storage medium of the photolithography system. For example, the auxiliary storage device 70 may store application programs, an OS image, and various data. The auxiliary storage device 70 may be provided in the form of a mass storage device such as a memory card (MultiMediaCart (MMC), embedded MMC (eMMC), secure digital card (SD), MicroSD, etc.), a Hard Disk Drive (HDD), a Solid State Drive (SSD), a Universal Flash Storage (UFS), and/or the like.

The system interconnector 90 may be a system bus for providing a network within the photolithography system. The processor 10, the working memory 30, the input/output device 50, and the auxiliary storage device 70 may be electrically connected and exchange data with one another through the system interconnector 90. However, the system interconnector 90 is not limited to the above description, and may further include relay means for efficient management.

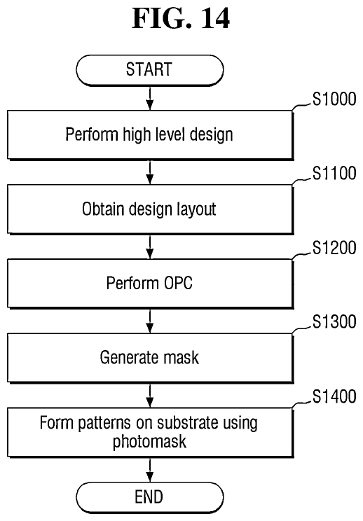

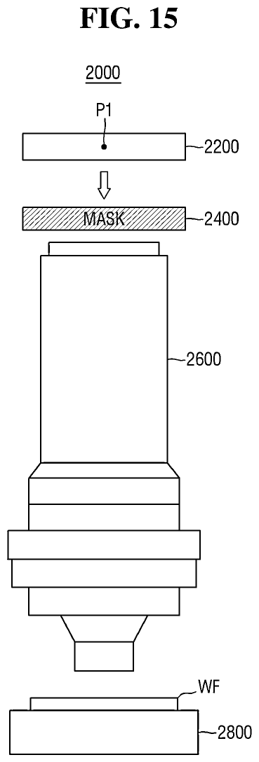

FIG. 14 is a flow chart illustrating a method for fabricating a semiconductor device according to some embodiments. In at least one embodiment, the method illustrated in FIG. 14 may be performed by a photolithography apparatus (e.g., the photolithography apparatus 2000 of FIG. 15) controlled by the photolithography system illustrated in FIG. 13.

Referring to FIG. 14, in the method for fabricating a semiconductor device according to some embodiments, a high level design of the semiconductor device is performed (S1000).

The high level design may mean that an integrated circuit for design is described in a high language of a computer language. For example, a high language such as a C-family language (e.g., portable C compiler (pcc), C++, etc.) may be used. Circuits designed by the high level design may be in more detail expressed by register transfer level (RTL) coding and/or simulation. In addition, a code generated by the register transfer level coding may be converted into a netlist and synthesized into the entire semiconductor device. The synthesized schematic circuit may be verified by a simulation tool, and an adjustment process may be accompanied in accordance with a verification result.

A design layout of a layer included in the semiconductor device is obtained (S1100).

The layout design for implementing a logically finished semiconductor device on a silicon substrate may be performed. For example, the layout design may be performed with reference to the schematic circuit synthesized in the high level design or the netlist corresponding thereto. The layout design may include a routing procedure for placing and connecting various standard cells provided in a cell library in accordance with a prescribed (or otherwise determined) design rule.

The cell library for layout design may include information on operation, speed, and power consumption of a standard cell. The cell library for expressing a circuit of a specific gate level as a layout is defined in most of layout design tools.

The layout may be a procedure for defining a shape and/or size of a pattern for configuring a transistor and metal lines to be actually formed on a silicon substrate. For example, in order to actually form an inverter circuit on a silicon substrate, layout patterns such as a p-type metal-oxide-semiconductor (PMOS), an N-type MOS (NMOS), an N-WELL, a gate electrode, metal lines, and/or the like to be disposed thereon may be properly disposed. To this end, a suitable one among inverters already defined in the cell library may be searched and selected.

In addition, routing for the selected and placed standard cells may be performed. For example, routing with upper lines may be performed on the selected and placed standard cells. The standard cells may be connected to each other in accordance with the design through the routing procedure. A series of processes of the aforementioned steps S1000 and S1100 may be performed automatically or manually by the design tool 32 of FIG. 13. Furthermore, placement and routing of the standard cells may be automatically performed using a separate Place & Routing tool.

After routing, verification of the layout as to whether there is a portion violating the design rule may be performed. Items for the verification may include a design rule check (DRC) that verifies whether the layout is properly performed to be suitable for the design rule, an electrical rule check (ERC) that verifies whether the layout is properly performed without electrical disconnection, and a Layout vs Schematic (LVS) that checks whether the layout is matched with a gate level netlist.

Optical proximity correction (OPC) is performed (S1200).

Layout patterns obtained through the layout design may be implemented on the silicon substrate by using the photolithography process, and OPC may be performed on the designed layout corresponding to the layout design (e.g., to compensate for the distortion phenomenon). While optical proximity correction is being performed, the shape and position of the patterns in the designed layout may be changed (biased). The OPC model used in optical proximity correction may be generated by the methods for generating an optical proximity correction model, which is described above with reference to FIGS. 1 to 12.

A photo mask is fabricated (S1300).

The photo mask is fabricated based on the design layout updated by optical proximity correction for the design layout and is configured to compensate for the distortion phenomenon). In general, the photo mask may be fabricated in a manner that depicts layout patterns using, e.g., a chromium film coated on a glass substrate, but the embodiments are not limited thereto.

A pattern may be formed on the substrate by using the photo mask (S1400). For example, a photolithography apparatus (e.g., 2000 of FIG. 15) may form the pattern using the photo mask. As a result, the semiconductor device may be fabricated.

Various types of exposure and etching processes may be repeated in the fabricating process of a semiconductor device using a photo mask. Through these processes, shapes of patterns configured during layout design may be sequentially formed on the silicon substrate.

FIG. 15 is a conceptual view illustrating a photolithography apparatus that uses a photo mask fabricated in accordance with some embodiments.

Referring to FIG. 15, a photolithography apparatus 2000 may include a light source 2200, a photo mask 2400, a reduced projection device 2600, and a substrate stage 2800.

However, the photolithography apparatus 2000 may further include components that are not shown in FIG. 15. For example, the photolithography apparatus 2000 may further include a sensor used to measure a height and slope of a surface of a substrate WF. In at least one embodiment, the photolithography apparatus 2000 is connected to a photolithography system (e.g., of FIG. 13) such that the photolithography system is enabled to update the OPC tool 34 based on data received from the sensor.

The light source 2200 may emit light. The light emitted from the light source 2200 may be irradiated to the photo mask 2400. For example, a lens may be provided between the light source 2200 and the photomask 2400 to adjust a light focus. The light source 2200 may include an ultraviolet light source (e.g., a KrF light source having a wavelength of about 234 nm, an ArF light source having a wavelength of about 193 nm, etc.). The light source 2200 may include one point light source P1, but the present disclosure is not limited thereto. In some embodiments, the light source 2200 may include a plurality of point light sources.

In order to print (implement) the designed layout on the substrate WF, the photo mask 2400 may include image patterns. The image patterns may be formed of a transparent area and an opaque area. The transparent area may be formed by etching a metal layer (e.g., a chromium film) on the photo mask 2400. The transparent area may allow the light emitted from the light source 2200 to pass through there. On the other hand, the opaque area may block the light without allowing (or reducing below an imaging threshold) the light to pass through there.

The reduced projection device 2600 may receive the light passing through the transparent area of the photo mask 2400. The reduced projection device 2600 may match layout patterns to be printed on the substrate WF with image patterns of the photo mask 2400. The substrate stage 2800 may support the substrate WF. For example, the substrate WF may include a silicon wafer.

The reduced projection device 2600 may include at least one aperture. The aperture may be used to increase a focal depth of the light emitted from the light source 2200. For example, the aperture may include a dipole aperture or a quadruple aperture. The reduced projection device 2600 may further include a lens to adjust a light focus. The reduced projection device 2600 may be configured to direct and/or focus the light towards the substrate WF.

The transparent area included in the image patterns of the photo mask 2400 may allow the light emitted from the light source 2200 to pass through there. The light passing through the photo mask 2400 may be irradiated onto the substrate WF through the reduced projection device 2600. Thus, patterns corresponding to the image patterns of the photo mask 2400 may be printed on the substrate WF.

Meanwhile, as the degree of integration of the semiconductor device is increased, a distance between the image patterns of the photo mask 2400 becomes very short, and a width of the transparent area becomes very narrow. Due to this “proximity”, interference and diffraction of light occur, and a distorted layout different from a desired layout may be printed on the substrate WF. When the distorted layout is printed on the substrate WF, the designed circuit may operate abnormally.

To avoid distortion of the layout, a resolution enhancement technique may be used. The optical proximity correction is an example of the resolution enhancement technique. According to the optical proximity correction, the degree of distortion such as interference and diffraction of light may be predicted in advance. Furthermore, based on the predicted result, image patterns to be formed in the photo mask 2400 may be pre-biased. As a result, a desired layout may be printed on the substrate WF.

In at least one embodiment, the optical proximity correction may be performed to adjust a layout for a single layer. Meanwhile, in a semiconductor process, the semiconductor device may be implemented to include a plurality of layers. For example, the semiconductor device may include a plurality of stacked metal layers to implement a specific circuit. Thus, the optical proximity correction may be performed independently for each of the plurality of layers.

Though an example is provided, the embodiments are not limited to the specific example provided in relation to FIG. 15. For example, unlike the aforementioned example, it is apparent to a person skilled in the art of the present disclosure that the configuration of the photolithography apparatus 2000 may be changed when an extreme ultraviolet (EUV) is used as the light source 2200.

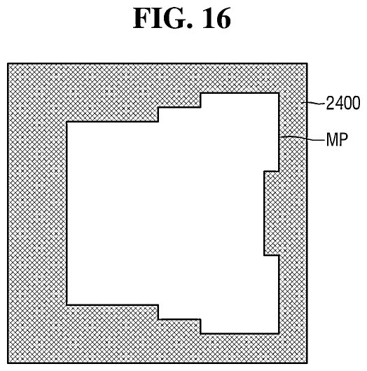

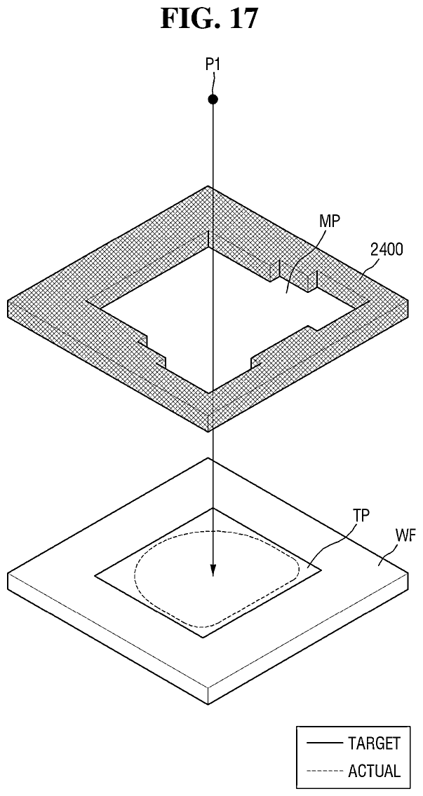

FIG. 16 is a view illustrating an example of a photo mask included in the photolithography system of FIG. 15. FIG. 17 is a view illustrating that a circuit pattern is printed on a substrate by using the photo mask of FIG. 16.

Referring to FIG. 16, the photo mask 2400 may include a mask pattern MP. The photo mask 2400 may include a transparent area and an opaque area. The opaque area may block light without allowing the light to pass through there. On the other hand, the transparent area may allow the light emitted from the light source 2200 of FIG. 15 to pass through there. The light passing through the photo mask 2400 may be irradiated onto the substrate WF of FIG. 15. The mask pattern MP may form the transparent area.

Referring to FIG. 17, the point light source P1 of the light source 2200 of FIG. 15 may emit light to the photo mask 2400.

The emitted light may pass through the transparent area of the mask pattern MP and be irradiated onto the substrate WF. As a result, the target pattern TP corresponding to the mask pattern MP may be printed on the substrate WF.

When the photo mask 2400 includes the mask pattern MP, an actual layout of a dotted line substantially the same (that is, having a small error) as a target layout of a solid line may be printed on the substrate WF. The actual layout of the dotted line may be similar to the target pattern TP described in FIGS. 1 to 12.

In concluding the detailed description, those skilled in the art will appreciate that many variations and modifications may be made to the preferred embodiments without substantially departing from the principles of the present invention. Therefore, the disclosed preferred embodiments of the invention are used in a generic and descriptive sense only and not for purposes of limitation.

What is claimed is:

1. A method for generating an optical proximity correction (OPC) model, the method comprising:
measuring a first target critical dimension (CD) value at a first measurement point of a scanning electron microscope (SEM) image for a target pattern and measuring a second target CD value at a second measurement point;
simulating the OPC model using the first target CD value with respect to a first evaluation point, corresponding to the first measurement point, on a contour of the OPC model;
simulating the OPC model using the second target CD value with respect to a second evaluation point, corresponding to the second measurement point, on the contour; and
fitting the OPC model to each of the first evaluation point and the second evaluation point.

2. The method of claim 1, further comprising:
measuring a first simulation CD value of the contour at the first evaluation point of the contour; and
measuring a second simulation CD value of the contour at the second evaluation point of the contour,
wherein the fitting the OPC model further includes correcting the OPC model using a cost function for the first target CD value, the second target CD value, the first simulation CD value, and the second simulation CD value.

3. The method of claim 1, further comprising:
setting a first measurement region on the SEM image, the first measurement region including the first measurement point and the second measurement point.

4. The method of claim 3, further comprising:
setting a first evaluation region on the contour such that the first evaluation region corresponds to the first measurement region; and
measuring, within the first evaluation region, a first simulation CD value of the first evaluation point of the contour and a second simulation CD value of the second evaluation point of the contour.

5. The method of claim 3, further comprising:
setting a second measurement region on the SEM image;
measuring a third target CD value at a third measurement point of the second measurement region;
measuring a fourth target CD value at a fourth measurement point of the second measurement region; and
determining a target CD average value based on the third target CD value and the fourth target CD value,
wherein the fitting the OPC model includes using the target CD average value with respect to a second evaluation region of the contour, and the second evaluation region corresponds to the second measurement region.

6. The method of claim 1, wherein a first distance between the first measurement point and the second measurement point on the SEM image and a second distance between the first evaluation point and the second evaluation point on the contour are different from each other.

7. The method of claim 1, further comprising:
determining an edge placement error (EPE) of the first evaluation point and the second evaluation point of the contour.

8. The method of claim 7, wherein the determining the EPE includes determining a first EPE corresponding to the first evaluation point and a second EPE corresponding to the second evaluation point, and
the fitting the OPC model is repeated until a cost function for the first EPE and the second EPE reaches a minimum.

9. The method of claim 1, wherein
the SEM image includes pixel data, and
the measuring the first target CD value at the first measurement point and the second target CD value at the second measurement point includes measuring the first target CD value and the second target CD value of the target pattern based on the pixel data of the SEM image.

10. A method for correcting a first optical proximity correction (OPC) model, the method comprising:
measuring a target critical dimension (CD) value of a target pattern for each of a plurality of measurement points of a scanning electron microscopy (SEM) image for the target pattern;
measuring a simulation CD value of a contour of the first OPC model for each of a plurality of evaluation points of a contour of the first OPC model for the target pattern, the plurality of evaluation points corresponding to the plurality of measurement points; and
fitting the first OPC model using all of the target CD values of the plurality of measurement points and all of the simulation CD values of the plurality of evaluation points.

11. The method of claim 10, further comprising:
setting the number of the plurality of measurement points, and
setting the number of the plurality of evaluation points.

12. The method of claim 10, further comprising:
determining an edge placement error (EPE) for the plurality of evaluation points of the contour.

13. The method of claim 10, wherein the plurality of measurement points are spaced apart from each other at constant intervals on the SEM image.

14. The method of claim 10, wherein the plurality of evaluation points are spaced apart from each other at constant intervals on the contour.

15. The method of claim 10, wherein the fitting the first OPC model includes generating a second OPC model such that a difference, using a cost function, between the target CD value of the plurality of measurement points and the simulation CD value of the plurality of evaluation points is less than or equal to a threshold value.

16. The method of claim 10, wherein the number of the plurality of measurement points and the number of the plurality of evaluation points are the same as each other.

17. The method of claim 10, wherein the plurality of measurement points include a first measurement point and a second measurement point,
the target pattern has a first target CD value at the first measurement point and a second target CD value at the second measurement point,
the plurality of evaluation points include a first evaluation point corresponding to the first measurement point and a second evaluation point corresponding to the second measurement point,
the contour of the first OPC model has a first simulation CD value at the first evaluation point and a second simulation CD value at the second evaluation point, and
the fitting the first OPC model includes fitting the first target CD value and the first simulation CD value with respect to the first evaluation point, and fitting the second target CD value and the second simulation CD value with respect to the second evaluation point.

18. The method of claim 10, further comprising:
setting a measurement region on the SEM image, the measurement region including the plurality of measurement points, on the SEM image.

19. A method for fabricating a semiconductor device, the method comprising:
fabricating a mask pattern; and
forming a pattern on a substrate using the mask,
wherein the fabricating the mask includes
designing a layout for the pattern,
generating an optical proximity correction (OPC) model for the layout,
correcting the layout using the optical proximity correction model, and
fabricating the mask with the corrected layout, and
the generating the optical proximity correction model includes
measuring a first target critical dimension (CD) value at a first measurement point of a scanning electron microscope (SEM) image of the pattern and measuring a second target CD value at a second measurement point of the SEM image of the pattern;
simulating the OPC model using the first target CD value with respect to a first evaluation point, corresponding to the first measurement point, on a contour of the OPC model;
simulating the OPC model using the second target CD value with respect to a second evaluation point, corresponding to the second measurement point, on the contour; and
fitting the OPC model to each of the first evaluation point and the second evaluation point.

20. The method of claim 19, wherein the generating the OPC model further includes determining an edge placement error (EPE) of the first evaluation point and the second evaluation point of the contour.
